(19) United States
(12) Patent Application Publication
(10) Pub. No.: US 2026/0005012 A1
(43) Pub. Date: Jan. 1, 2026

(54) WAFER CLEANING METHOD AND APPARATUS

(71) Applicant: Shanghai Huali Microelectronics Corporation, Shanghai (CN)

(72) Inventors: Quan ZHANG, Shanghai (CN); Qingpeng ZHAO, Shanghai (CN); Jingang TONG, Shanghai (CN)

(21) Appl. No.: 19/040,158

(22) Filed: Jan. 29, 2025

(30) Foreign Application Priority Data
Jun. 28, 2024 (CN) 202410865153.6

(51) Int. Cl. H01L 21/02; H01L 21/67; H01L 21/687

(52) U.S. Cl. CPC H01L 21/0209; H01L 21/67051; H01L 21/6875

(57) ABSTRACT

The present disclosure discloses a wafer cleaning method including: providing a wafer; placing the wafer on a chuck in a cleaning chamber, and configuring a first distance between the side not to be cleaned and the surface of the chuck; flowing a protective gas, and configuring a first flow rate of the protective gas; and introducing a cleaning fluid above a side to be cleaned. The magnitude of the first flow rate is configured so that the cleaning fluid does not flow back from the edge of the wafer to the side not to be cleaned. The first distance is configured according to a first pressure formed by the protective gas of the first flow rate on the side not to be cleaned, the first pressure is less than a minimum pressure that causes a pattern structure on the side not to be cleaned of the wafer to collapse.

### CROSS-REFERENCES TO RELATED APPLICATIONS

This application claims priority to Chinese patent application No. 202410865153.6, filed on Jun. 28, 2024, the disclosure of which is incorporated herein by reference in its entirety.

### TECHNICAL FIELD

The present disclosure relates to the field of semiconductor integrated circuit manufacturing, and particularly relates to a wafer cleaning method; the present disclosure also relates to a wafer cleaning apparatus.

### BACKGROUND

In an existing backside clean process of a polysilicon (poly) loop, a pattern on a front side of a wafer is protected by reducing an N₂ flow rate. However, the reduction of the N₂ flow rate causes an acid fluid on the backside to flow back to the front side of the wafer, thereby causing acid erosion on the front side of the wafer, leading to problems of serious edge residue and particulate (PA) contamination defects.

### BRIEF SUMMARY

According to some embodiments in this application, a wafer cleaning method is disclosed in the following steps:
providing a wafer including a side to be cleaned and a side not to be cleaned, where the side not to be cleaned has a pattern structure;
placing the wafer on a chuck in a cleaning chamber, and configuring a first distance between the side not to be cleaned and the surface of the chuck during wafer cleaning;
flowing a protective gas from a gas hole of the chuck to the side not to be cleaned, and configuring a first flow rate of the protective gas; and
introducing a cleaning fluid above the side to be cleaned to implement the wafer cleaning, where
the magnitude of the first flow rate is configured so that the cleaning fluid does not flow back from the edge of the wafer to the side not to be cleaned;
the first distance is configured according to a first pressure formed by the protective gas of the first flow rate on the side not to be cleaned, the first pressure is less than a minimum pressure that causes the pattern structure to collapse, and when the first flow rate is fixed, the first pressure is smaller if the first distance is larger.

In some cases, the chuck is provided with an pins, the wafer is placed on the chuck by means of the pins, the pins is located at a first process position during the wafer cleaning, and a distance between a top surface of the pins at the first process position and the surface of the chuck is the first distance.

In some cases, the length of the pins corresponds to the first distance, and the first distance is configured by selecting the pins of a corresponding length; and when the magnitude of the first distance is determined, the pins of the length corresponding to the first distance is selected.

In some cases, the method further includes: prior to the wafer cleaning, configuring a first distribution structure of the gas holes in the chuck, where the first distribution structure ensures that the protective gas has a second flow rate over an edge region of the wafer on the premise of the first flow rate over a region enclosed by the edge region of the wafer, and the second flow rate is greater than the first flow rate, so as to enhance protection for the edge of the wafer during the wafer cleaning.

In some cases, the surface of the chuck is circular, and the center of the chuck is aligned with the center of the wafer during the wafer cleaning;
all the gas holes in the first distribution structure are distributed in more than two circles; and during the wafer cleaning, an outermost circle in the first distribution structure is located directly below the edge region of the wafer.

In some cases, the protective gas includes nitrogen.

In some cases, the material of the wafer includes silicon; a semiconductor device is formed on a front side of the wafer and includes a gate structure, and the gate structure includes a gate dielectric layer and a gate conductive material layer stacked in sequence.

In some cases, the side to be cleaned is a backside of the wafer, and the side not to be cleaned is the front side of the wafer;
and the pattern structure includes a pattern of the gate conductive material layer.

In some cases, the material of the gate conductive material layer includes polysilicon.

To solve the above technical problem, in the wafer cleaning apparatus provided by the present disclosure the chuck is provided with an pins, the wafer is placed on the chuck by means of the pins, the pins is located at a first process position during the wafer cleaning, and a distance between a top surface of the pins at the first process position and the surface of the chuck is the first distance.

In some cases, the pins including more than two lengths are provided for selection, the length of the pins corresponds to the first distance, and the first distance is configured by selecting the pins of a corresponding length; and when the magnitude of the first distance is determined, the pins of the length corresponding to the first distance is selected.

In some cases, the gas holes are arranged in the chuck to form a first distribution structure;
the first distribution structure ensures that the protective gas has a second flow rate over an edge region of the wafer on the premise of the first flow rate over a region enclosed by the edge region of the wafer, and the second flow rate is greater than the first flow rate, so as to enhance protection for the edge of the wafer during the wafer cleaning.

In some cases, the surface of the chuck is circular, and the center of the chuck is aligned with the center of the wafer during the wafer cleaning;
all the gas holes in the first distribution structure are distributed in more than two circles; and during the wafer cleaning, an outermost circle in the first distribution structure is located directly below the edge region of the wafer.

In some cases, the protective gas includes nitrogen.

Different from the prior art in which the pressure, i.e., the first pressure, on the side not to be cleaned is lowered by reducing the flow rate of the protective gas, i.e., the first flow rate, thus preventing the pattern structure from collapsing, in the present disclosure, the first pressure is adjusted by configuring the first distance between the side not to be cleaned and the surface of the chuck, so that the first flow rate can be configured independently of the first pressure, enabling the first pressure to satisfy a requirement while enabling the first flow rate not to be reduced and thus to satisfy a requirement. That is, the protection for the edge region of the wafer may be ensured without reducing the first flow rate, thereby preventing the cleaning fluid from flowing back from the side to be cleaned to the side not to be cleaned and thus avoiding the erosion on the edge of the wafer. Accordingly, in the present disclosure, the adjustment configuration of the first distance is added so that the first pressure and the first flow rate can be adjusted independently, so as to prevent the pattern structure of the side not to be cleaned from collapsing and prevent the cleaning fluid from flowing back from the side to be cleaned to the side not to be cleaned and thus avoid the erosion on the edge of the wafer, finally improving a product yield.

Moreover, in the prior art, the length of the pins in the cleaning chamber is fixed, and a process position of the pins, i.e., the first process position, is unchanged during the wafer cleaning. On the basis of the prior art, in the present disclosure, pins of different lengths are employed without changing a condition for controlling the first process position of the pins, so as to enable the first distance to reach a required value in the case of the first process position. Accordingly, the present disclosure breaks through a defect that the first distance is unadjustable under the condition that the first process position of the cleaning chamber is controlled as being fixed in the prior art, and thus is finally able to solve the technical problem of the present disclosure.

Furthermore, in the prior art, the first distribution structure of the gas holes in the chuck is configured based on that flow rates of the protective gas reaching various regions of the side not to be cleaned of the wafer are uniformly distributed. In the present disclosure, targeted improvement is made to the first distribution structure, so that the protective gas has the larger second flow rate over the edge region of the wafer on the premise of uniform distribution of the first flow rate over the region enclosed by the edge region of the wafer, which can further enhance the protection for the edge of the wafer during the wafer cleaning.

### BRIEF DESCRIPTION OF THE DRAWINGS

The present disclosure is further described in detail below with reference to the drawings and specific embodiments:

FIG. 1A is a schematic diagram of a distribution structure of gas holes of a chuck in an existing cleaning chamber;

FIG. 1B is a diagram of a structure inside the cleaning chamber in an existing wafer cleaning method;

FIG. 2 is a flowchart of a wafer cleaning method according to an embodiment of the present disclosure;

FIG. 3A is a schematic diagram of a first distribution structure of gas holes of a chuck in the wafer cleaning method according to an embodiment of the present disclosure; and

FIG. 3B is a diagram of a structure inside the cleaning chamber in the wafer cleaning method according to an embodiment of the present disclosure.

### DETAILED DESCRIPTION OF THE DISCLOSURE

Before the technical solution of embodiments of the present disclosure is described in detail, the technical problem in the existing wafer cleaning method is further described.

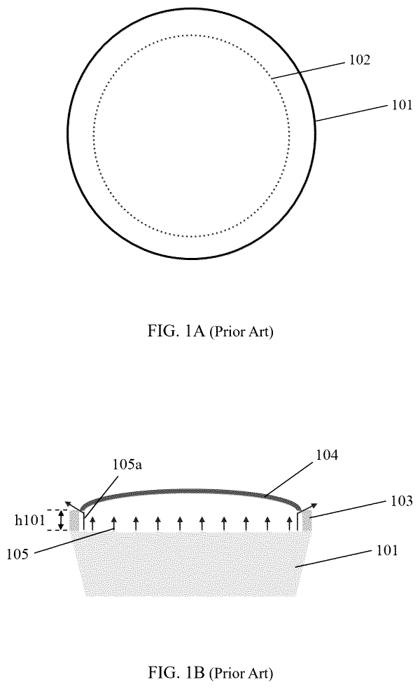

FIG. 1A is a schematic diagram of a distribution structure of gas holes of a chuck in an existing cleaning chamber. It can be seen that a distribution structure 102 composed of gas holes arranged in a circle is formed in the chuck 101.

FIG. 1B is a diagram of a structure inside the cleaning chamber in the existing wafer cleaning method. The chuck is provided with pins 103, and after a wafer 104 is placed on the pins 103, a distance between the wafer 104 and the surface of the chuck 101 is determined by a distance h101 between a top surface of the pins 103 and the surface of the chuck 101.

During wafer cleaning, N₂ flows out from the gas holes and forms a protective layer on a side not to be cleaned of the wafer 104, and depending on different gas flow rates, different pressures are finally formed on the side not to be cleaned of the wafer 103. When there is a pattern structure on the side not to be cleaned, the pattern structure may collapse after the pressure exceeds a specific value, and the higher the pressure, the larger the number of collapsed patterns. In the existing method, in order to prevent the pattern structure from collapsing, the pressure is lowered by reducing the gas flow rate. However, the reduction of the gas flow rate causes a new technical problem, which is likely to make the cleaning fluid on the side to be cleaned flow back onto the side not to be cleaned. In FIG. 1B, an arrow line 105 represents N₂ gas flow, where gas flow in the edge region of the wafer 104 is separately represented by an arrow line 105a. In the edge region of the wafer 104, the gas flow represented by the arrow line 105a is required to be capable of flowing outward, to form a pressure to counteract a force that makes the cleaning fluid flow back from the side to be cleaned to the side not to be cleaned along the edge of the wafer 103. When the gas flow rate is reduced, the pressure formed by the gas flow is lowered, eventually causing backflow of the cleaning fluid. The cleaning fluid that flows back erodes the structure on the side not to be cleaned, not only forming a residue of the cleaning fluid, but also forming a large particulate defect. Therefore, in the existing method, there is a contradiction between adjustments of the gas flow rate of the protective gas and the pressure formed on the side not to be cleaned. If the gas flow rate is excessively large, the pressure is excessively large such that the pattern collapse is likely to occur; and if the gas flow rate is excessively small, the backflow of the cleaning fluid is likely to occur, thereby forming the residue and the particulate defect. Both cases result in a reduction of the product yield.

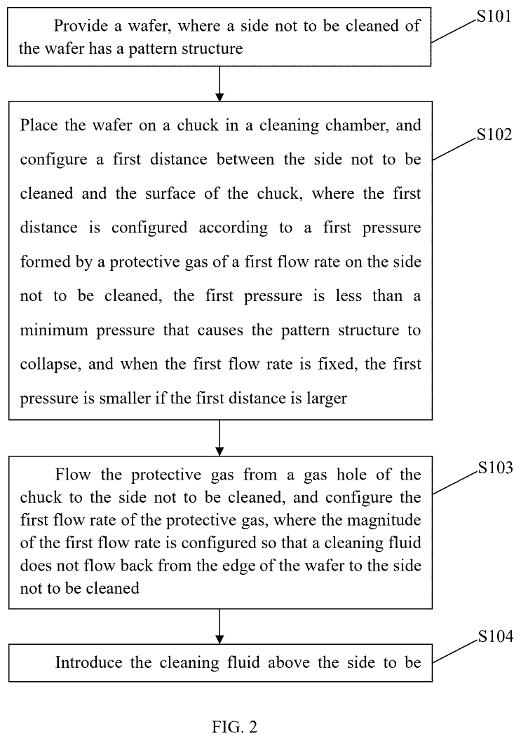

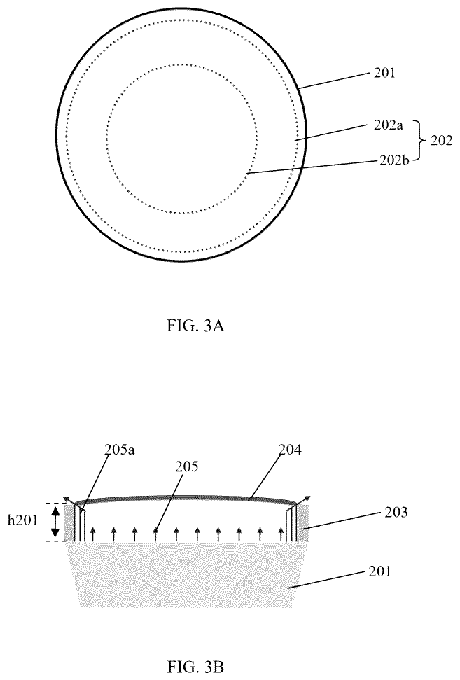

FIG. 2 is a flowchart of a wafer cleaning method according to an embodiment of the present disclosure. FIG. 3A is a schematic diagram of a first distribution structure 202 of gas holes of a chuck 201 in the wafer cleaning method according to the embodiment of the present disclosure. FIG. 3B is a diagram of a structure inside the cleaning chamber in the wafer cleaning method according to the embodiment of the present disclosure. The wafer cleaning method according to the embodiment of the present disclosure includes the following steps.

Step S101: Referring to FIG. 3B, a wafer 204 including a side to be cleaned and a side not to be cleaned is provided, where the side not to be cleaned has a pattern structure.

Step S102: Referring to FIG. 3B, the wafer 204 is placed on a chuck 201 in a cleaning chamber, and a first distance h201 between the side not to be cleaned and the surface of the chuck 201 during wafer cleaning is configured.

In the embodiment of the present disclosure, the chuck 201 is provided with an pins 203, the wafer 204 is placed on the chuck 201 by means of the pins 203, the pins 203 is located at a first process position during the wafer cleaning, and a distance between a top surface of the pins 203 at the first process position and the surface of the chuck 201 is the first distance h201. Compared with the distance h101 shown in FIG. 1B, the first distance h201 of the embodiment of the present disclosure is larger.

The first distance h201 is configured according to a first pressure formed by the protective gas of the first flow rate on the side not to be cleaned as described below, the first pressure is less than a minimum pressure that causes the pattern structure to collapse, and when the first flow rate is fixed, the first pressure is smaller if the first distance h201 is larger. That is, in the embodiment of the present disclosure, the first pressure is lowered by increasing the first distance h201. The first pressure is lowered below a lower limit, i.e., the minimum pressure, so that the pattern structure does not collapse during the wafer cleaning.

In the embodiment of the present disclosure, the length of the pins 203 corresponds to the first distance h201, and the first distance h201 is configured by selecting the pins 203 of a corresponding length; and when the magnitude of the first distance h201 is determined, the pins 203 of the length corresponding to the first distance h201 is selected. The pins 203 shown in FIG. 3B is at the first process position. The first process position may be controlled by a movement control apparatus of the pins 203. The bottom of the pins 203 is arranged on the movement control apparatus, so that when the movement control apparatus arranges the pins 203 at the first process position, a bottom surface of the pins 203 is moved to the first process position. In this case, after the length of the pins 203 increases, the first distance h201 also increases. Therefore, in the embodiment of the present disclosure, the adjustment of the first distance h201 may be implemented just by configuring the length of the pins 203, without any change in the movement control apparatus and the control on the first process position.

Step S103: A protective gas is flowed from a gas hole of the chuck 201 to the side not to be cleaned, and a first flow rate of the protective gas configured.

In the embodiment of the present disclosure, the magnitude of the first flow rate is configured so that the cleaning fluid does not flow back from the edge of the wafer 204 to the side not to be cleaned.

In the embodiment of the present disclosure, the method further includes: referring to FIG. 3A, prior to the wafer cleaning, configuring a first distribution structure 202 of the gas holes in the chuck 201, where the first distribution structure 202 ensures that the protective gas has a second flow rate over an edge region of the wafer 204 on the premise of the first flow rate over a region enclosed by the edge region of the wafer 204, and the second flow rate is greater than the first flow rate, so as to enhance protection for the edge of the wafer 204 during the wafer cleaning. Referring to FIG. 3B, gas flow over the region enclosed by the edge region of the wafer 204 is represented by an arrow line 205, and gas flow in the edge region of the wafer 204 is separately represented by an arrow line 205a. As can be seen, the arrow lines 205 are uniformly distributed, indicating the uniform distribution of the first flow rate; and the arrow lines 205a are more dense, indicating that the second flow rate is greater than the first flow rate. When the second flow rate is increased, at the edge of the wafer 204, it is ensured that there is enough protective gas flowing outward from the side not to be cleaned. As such, during the subsequent wafer cleaning, the cleaning fluid cannot flow back from the side to be cleaned to the side not to be cleaned along the edge of the wafer 204, thereby enhancing the protection for the edge of the wafer 204.

Referring to FIG. 3A, the surface of the chuck 201 is circular, and the center of the chuck 201 is aligned with the center of the wafer 204 during the wafer cleaning.

In some embodiments, all the gas holes in the first distribution structure 202 are distributed in more than two circles; and during the wafer cleaning, an outermost circle in the first distribution structure 202 is located directly below the edge region of the wafer 204. Two circles are shown in FIG. 3A, which are circles 202a and 202b, respectively, where in FIG. 3B, the outer circle 202b is located directly below the edge region of the wafer 204.

In some embodiments, the protective gas includes nitrogen. In other embodiments, the protective gas may also be selected as desired, for example, other suitable inert gases may be employed.

Step S104: A cleaning fluid is introduced above the side to be cleaned to implement the wafer cleaning.

In the embodiment of the present disclosure, the material of the wafer 204 includes silicon; a semiconductor device is formed on a front side of the wafer 204 and includes a gate structure, and the gate structure includes a gate dielectric layer and a gate conductive material layer stacked in sequence.

The side to be cleaned is a backside of the wafer 204, and the side not to be cleaned is the front side of the wafer 204.

The pattern structure includes a pattern of the gate conductive material layer.

The material of the gate conductive material layer includes polysilicon.

During the wafer cleaning, the protective gas flows at the first flow rate, so as to prevent the backflow of the cleaning fluid and thus prevent erosion caused by the backflow of the cleaning fluid, thereby preventing the problem of edge residue and particulate contamination caused by the erosion of the cleaning fluid. In use of the existing method, the protective gas flowing at the first flow rate may cause the first pressure to be excessively large, leading to the collapse of the pattern structure. However, in the embodiment of the present disclosure, the first pressure may be effectively lowered without reducing the first flow rate, so that the embodiment of the present disclosure does not lead to the collapse of the pattern structure.

Different from the prior art in which the pressure, i.e., the first pressure, on the side not to be cleaned is lowered by reducing the flow rate of the protective gas, i.e., the first flow rate, thus preventing the pattern structure from collapsing, in the embodiment of the present disclosure, the first pressure is adjusted by configuring the first distance h201 between the side not to be cleaned and the surface of the chuck 201, so that the first flow rate can be configured independently of the first pressure, enabling the first pressure to satisfy a requirement while enabling the first flow rate not to be reduced and thus to satisfy a requirement. That is, the protection for the edge region of the wafer 204 may be ensured without reducing the first flow rate, thereby preventing the cleaning fluid from flowing back from the side to be cleaned to the side not to be cleaned and thus avoiding the erosion on the edge of the wafer 204. Accordingly, in the embodiment of the present disclosure, the adjustment configuration of the first distance h201 is added so that the first pressure and the first flow rate can be adjusted independently, so as to prevent the pattern structure of the side not to be cleaned from collapsing and prevent the cleaning fluid from flowing back from the side to be cleaned to the side not to be cleaned and thus avoid the erosion on the edge of the wafer 204, thereby avoiding the edge residue and particulate defect, finally improving a product yield.

Moreover, in the prior art, the length of the pins 203 in the cleaning chamber is fixed, and a process position of the pins 203, i.e., the first process position, is unchanged during the wafer cleaning. On the basis of the prior art, in the embodiment of the present disclosure, pins 203 of different lengths are employed without changing a condition for controlling the first process position of the pins 203, so as to enable the first distance h201 to reach a required value in the case of the first process position. Accordingly, the embodiment of the present disclosure breaks through a defect that the first distance h201 is unadjustable under the condition that the first process position of the cleaning chamber is controlled as being fixed in the prior art, and thus is finally able to solve the technical problem of the present disclosure.

Furthermore, in the prior art, the first distribution structure 202 of the gas holes in the chuck 201 is configured based on that flow rates of the protective gas reaching various regions of the side not to be cleaned of the wafer 204 are uniformly distributed. In the embodiment of the present disclosure, targeted improvement is made to the first distribution structure 202, so that the protective gas has the larger second flow rate over the edge region of the wafer 204 on the premise of uniform distribution of the first flow rate over the region enclosed by the edge region of the wafer 204, which can further enhance the protection for the edge of the wafer 204 during the wafer cleaning.

In wafer cleaning apparatus of the embodiment of the present disclosure, the chuck 201 is provided with an pins 203, the wafer 204 is placed on the chuck 201 by means of the pins 203, the pins 203 is located at a first process position during the wafer cleaning, and a distance between a top surface of the pins 203 at the first process position and the surface of the chuck 201 is the first distance h201. Compared with the distance h101 shown in FIG. 1B, the first distance h201 of the embodiment of the present disclosure is larger.

In some embodiments, the pins 203 including more than two lengths are provided for selection, the length of the pins 203 corresponds to the first distance h201, and the first distance h201 is configured by selecting the pins 203 of a corresponding length; and when the magnitude of the first distance h201 is determined, the pins 203 of the length corresponding to the first distance h201 is selected.

The gas holes are arranged in the chuck 201 to form a first distribution structure 202.

The first distribution structure 202 ensures that the protective gas has a second flow rate over an edge region of the wafer 204 on the premise of the first flow rate over a region enclosed by the edge region of the wafer 204, and the second flow rate is greater than the first flow rate, so as to enhance protection for the edge of the wafer 204 during the wafer cleaning.

The surface of the chuck 201 is circular, and the center of the chuck 201 is aligned with the center of the wafer 204 during the wafer cleaning.

All the gas holes in the first distribution structure 202 are distributed in more than two circles; and during the wafer cleaning, an outermost circle in the first distribution structure 202 is located directly below the edge region of the wafer 204.

The protective gas includes nitrogen.

The present disclosure is described in detail above through specific embodiments that, however, do not impose limitations to the present disclosure. Without departing from the principle of the present disclosure, a skilled in the art may also made many other deformations and improvements, which should also be considered as the scope of protection of the present disclosure.

What is claimed is:

1. A wafer cleaning method, comprising:
providing a wafer comprising a side to be cleaned and a side not to be cleaned, wherein the side not to be cleaned has a pattern structure;
placing the wafer on a chuck in a cleaning chamber, and configuring a first distance between the side not to be cleaned and the surface of the chuck during wafer cleaning;
flowing a protective gas from a gas hole of the chuck to the side not to be cleaned, and configuring a first flow rate of the protective gas; and
introducing a cleaning fluid above the side to be cleaned to implement the wafer cleaning, wherein
the magnitude of the first flow rate is configured so that the cleaning fluid does not flow back from the edge of the wafer to the side not to be cleaned;
the first distance is configured according to a first pressure formed by the protective gas of the first flow rate on the side not to be cleaned, the first pressure is less than a minimum pressure that causes the pattern structure to collapse, and when the first flow rate is fixed, the first pressure is smaller if the first distance is larger.

2. The wafer cleaning method according to claim 1, wherein the chuck is provided with pins, the wafer is placed on the chuck by means of the pins, the pins is located at a first process position during the wafer cleaning, and a distance between a top surface of the pins at the first process position and the surface of the chuck is the first distance.

3. The wafer cleaning method according to claim 2, wherein the length of the pins corresponds to the first distance, and the first distance is configured by selecting the pins of a corresponding length; and when the magnitude of the first distance is determined, the pins of the length corresponding to the first distance is selected.

4. The wafer cleaning method according to claim 1, further comprising: prior to the wafer cleaning, configuring a first distribution structure of the gas holes in the chuck, wherein the first distribution structure ensures that the protective gas has a second flow rate over an edge region of the wafer on the premise of the first flow rate over a region enclosed by the edge region of the wafer, and the second flow rate is greater than the first flow rate, so as to enhance protection for the edge of the wafer during the wafer cleaning.

5. The wafer cleaning method according to claim 4, wherein the surface of the chuck is circular, and the center of the chuck is aligned with the center of the wafer during the wafer cleaning;
all the gas holes in the first distribution structure are distributed in more than two circles;
and during the wafer cleaning, an outermost circle in the first distribution structure is located directly below the edge region of the wafer.

6. The wafer cleaning method according to claim 1, wherein the protective gas comprises nitrogen.

7. The wafer cleaning method according to claim 1, wherein the material of the wafer comprises silicon; a semiconductor device is formed on a front side of the wafer and comprises a gate structure, and the gate structure comprises a gate dielectric layer and a gate conductive material layer stacked in sequence.

8. The wafer cleaning method according to claim 7, wherein the side to be cleaned is a backside of the wafer, and the side not to be cleaned is the front side of the wafer;
and the pattern structure comprises a pattern of the gate conductive material layer.

9. The wafer cleaning method according to claim 8, wherein the material of the gate conductive material layer comprises polysilicon.

10. A wafer cleaning apparatus for implementing the wafer cleaning method according to claim 1, wherein the chuck is provided with an pins, the wafer is placed on the chuck by means of the pins, the pins is located at a first process position during the wafer cleaning, and a distance between a top surface of the pins at the first process position and the surface of the chuck is the first distance.

11. The wafer cleaning apparatus according to claim 10, wherein the pins comprising more than two lengths are provided for selection, the length of the pins corresponds to the first distance, and the first distance is configured by selecting the pins of a corresponding length;
and when the magnitude of the first distance is determined, the pins of the length corresponding to the first distance is selected.

12. The wafer cleaning apparatus according to claim 10, wherein the gas holes are arranged in the chuck to form a first distribution structure;
the first distribution structure ensures that the protective gas has a second flow rate over an edge region of the wafer on the premise of the first flow rate over a region enclosed by the edge region of the wafer, and the second flow rate is greater than the first flow rate, so as to enhance protection for the edge of the wafer during the wafer cleaning.

13. The wafer cleaning apparatus according to claim 12, wherein the surface of the chuck is circular, and the center of the chuck is aligned with the center of the wafer during the wafer cleaning;
all the gas holes in the first distribution structure are distributed in more than two circles;
and during the wafer cleaning, an outermost circle in the first distribution structure is located directly below the edge region of the wafer.

14. The wafer cleaning apparatus according to claim 10, wherein the protective gas comprises nitrogen.
